(19) United States
(12) Patent Application Publication
(10) Pub. No.: US 2010/0108115 A1
(43) Pub. Date: May 6, 2010

(54) BULK THERMOELECTRIC MATERIAL AND THERMOELECTRIC DEVICE COMPRISING THE SAME

(75) Inventors: Kyu-hyoung LEE, Yongin-si (KR); Sang-mock LEE, Yongin-si (KR); Eun-sung LEE, Seoul (KR); Il-ho KIM, Chungju-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/604,786

(22) Filed: Oct. 23, 2009

(30) Foreign Application Priority Data
Oct. 23, 2008 (KR) 10-2008-0104263

(51) Int. Cl. H01L 35/12

(52) U.S. Cl. 136/236.1

(57) ABSTRACT

A bulk thermoelectric material having a structure in which migration of carriers is not inhibited but phonons are scattered is described. The bulk thermoelectric material includes: a bulk crystalline thermoelectric material matrix; and nanoparticles coated with a conductive material within the thermoelectric material matrix.

### CROSS-REFERENCE TO RELATED APPLICATIONS

This application claims priority to Korean Patent Application No. 10-2008-0104263, filed on Oct. 23, 2008, and all the benefits accruing therefrom under 35 U.S.C. §119, the contents of which in its entirety are herein incorporated by reference.

### BACKGROUND

1. Field

This disclosure relates to a bulk thermoelectric material having excellent thermoelectric energy conversion efficiency and more particularly, to a thermoelectric material including a bulk crystalline thermoelectric material matrix and nanoparticles.

2. Description of the Related Art

The thermoelectric effect is a reversible and direct conversion of a temperature difference to electric voltage and vice versa, caused by the migration of electrons and holes. The thermoelectric effect encompasses the Peltier effect, which is a temperature difference created by supplying currents to two ends of a thermoelectric material, and which is generally applied to cooling systems; and the Seebeck effect, which is an electromotive force created by a temperature difference between two ends of a thermoelectric material, and which is generally applied to power generation systems.

There is an increasing demand for overcoming the effects of heat generation in existing high temperature electronic devices, in particular those which cannot be addressed by existing refrigerant gas compression systems. There is also an increasing demand for developing a material suitable for use in active cooling systems and precision temperature control systems applied to deoxyribonucleic acid (“DNA”). Thermoelectric cooling is an environmentally friendly technology that does not generate vibration or noise. It further does not use a refrigerant gas that can cause environmental problems. A highly efficient thermoelectric cooling material may be applied to universal cooling systems such as refrigerators, air conditioners, and the like. In addition, power generation may be performed using a temperature difference between both ends of a thermoelectric material in automotive engines, industrial plants, and the like, in which heat is dissipated. Such thermoelectric power generation systems are already used in spacecraft that travel to Mars, Saturn, or the like, in which solar energy is not available.

Low energy conversion efficiency is a significant factor inhibiting the application of thermoelectric materials in thermoelectric cooling and power generation. The performance of a thermoelectric material may be evaluated using a dimensionless figure of merit ZT, as defined in Equation 1 below.

$$ZT = \frac{{S}^{2} σ T}{κ} \qquad ( 1 )$$

In Equation 1, ZT is a figure of merit, S is a Seebeck coefficient (milliwatts per degree Kelvin (mW K⁻¹)), σ is electrical conductivity (Siemens per centimeter (Scm⁻¹)), T is absolute temperature (Kelvin (K)), and κ is thermal conductivity (Watts per meter per degree Kelvin (Wm⁻¹K⁻¹)).

However, the value of ZT has a limited range since the electrical conductivity and the Seebeck coefficient have a trade-off relationship by which when one of the electrical conductivity or the Seebeck coefficient is increased, the other is decreased. Thus, it would be desirable to develop methods and materials directed to increasing the Seebeck coefficient and the electrical conductivity, i.e., a power factor (S²σ), and decreasing the thermal conductivity in order to increase the figure of merit ZT, as defined in Equation 1.

### SUMMARY

One or more embodiments include a bulk thermoelectric material having a structure in which the migration of electrons is not blocked but phonons are scattered.

One or more embodiments include a thermoelectric device including the bulk thermoelectric material.

Additional aspects will be set forth in part in the description which follows and, in part, will be apparent from the description, or may be learned by practice of the invention.

To achieve the above and/or other aspects, one or more embodiments includes a thermoelectric material including: a bulk crystalline thermoelectric material matrix; and nanoparticles coated with a conductive material within the bulk crystalline thermoelectric material. The nanoparticles coated with the conductive material may be embedded in the bulk crystalline thermoelectric material matrix.

The nanoparticles may be metal particles or ceramic particles. About 30 to about 100% of the surface of the nanoparticles may be coated with the conductive material.

A binding force between the nanoparticles and the conductive material may be greater than that between the atoms in the crystalline structure of the thermoelectric material matrix.

A diameter of the nanoparticles may be similar to the size of a mean free path of the phonon. The difference between the diameter of the nanoparticles and the size of the mean free path of the phonon may be 0 to about 7 nm. The diameter of the nanoparticles may be about 1 nm to about 50 nm.

A thickness of the conductive material may be similar to the size of a mean free path of the phonon. The difference between a thickness of the conductive material and the size of a mean free path of the phonon may be 0 to about 5 nm.

The volume of the nanoparticles may be from about 0.5 to about 15% of the total volume of the thermoelectric material.

To achieve the above and/or other aspects, one or more embodiments may include a thermoelectric device including the thermoelectric material.

### BRIEF DESCRIPTION OF THE DRAWINGS

The above and/or other aspects, advantages, and features of this disclosure will become more apparent and more readily appreciated from the following description of the embodiments, taken in conjunction with the attached drawings, in which:

FIG. 1 schematically illustrates an exemplary embodiment of a phonon blocking-electron transmitting structure of a thermoelectric material;

FIG. 2 schematically illustrates an exemplary embodiment of a thermoelectric material having a phonon blocking-electron transmitting structure;

FIG. 3 schematically illustrates an exemplary embodiment of an active cooling device;

FIG. 4 schematically illustrates an exemplary embodiment of a temperature difference power generation system;

FIG. 5 schematically illustrates an exemplary embodiment of a thermoelectric module;

FIG. 6 is a transmission electron microscope (“TEM”) image of nanoparticles coated with a conductive material prepared according to Example 1;

FIG. 7 is a graph illustrating the results of element analysis of the nanoparticles coated with the conductive material prepared according to Example 1;

FIG. 8 is a graph of the electrical conductivity (S cm⁻¹) versus temperature (K) of the thermoelectric materials prepared according to Examples 1 and 2 and Comparative Example 1;

FIG. 9 is a graph of the Seebeck coefficient (mW K⁻¹) versus temperature (K) of the thermoelectric materials prepared according to Examples 1 and 2 and Comparative Example 1;

FIG. 10 is a graph of the thermal conductivity (W m⁻¹K⁻¹) versus temperature (K) of the thermoelectric materials prepared according to Examples 1 and 2 and Comparative Example 1; and

FIG. 11 is a graph of the figure of merit ZT according to temperature (K) of the thermoelectric materials prepared according to Examples 1 and 2 and Comparative Example 1.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Spatially relative terms, such as “lower,” “under,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” or “under” relative to other elements or features would then be oriented “upper” or “over” relative to the other elements or features. Thus, the exemplary term “under” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to limit the claims. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments are described herein with reference to cross-section illustrations that are schematic illustrations of idealized embodiments (and intermediate structures). As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely for illustration and does not pose a limitation on the scope of the disclosure unless otherwise claimed. No language in the specification should be construed as indicating any non-claimed element as essential.

In order to increase a figure of merit ZT of a thermoelectric material, a microstructure in which phonons are scattered but carriers are not scattered, i.e., a phonon blocking-electron transmitting structure, is suggested, as illustrated in FIG. 1. In this regard, FIG. 1 schematically illustrates a phonon blocking-electron transmitting structure of a thermoelectric material.

For example, a method of increasing a figure of merit of a thermoelectric material by inducing the scattering of phonons at the interfaces of a thin film thermoelectric material by regulating the properties of the interfaces such as the size has been suggested. However, since thin film thermoelectric materials are manufactured using physical deposition, the thickness thereof is limited to several micrometers (μm). Because heat is not dissipated in the thickness direction, a temperature difference is not maintained. Furthermore, the application of thin film thermoelectric materials is limited, except to micro-cooling fields, due to high manufacturing costs.

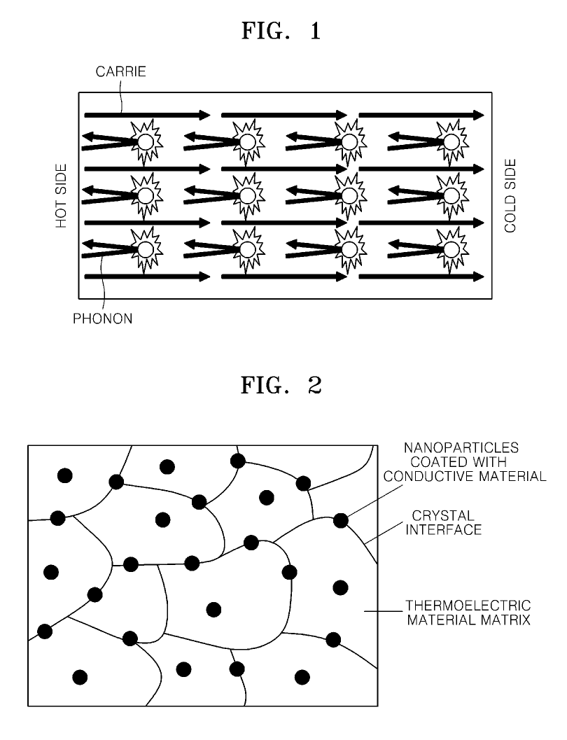

FIG. 2 schematically illustrates a thermoelectric material having a phonon blocking-electron transmitting structure, according to one embodiment. Referring to FIG. 2, the thermoelectric material includes: a bulk crystalline thermoelectric material matrix; and nanoparticles coated with a conductive material. The nanoparticles coated with the conductive material may be embedded in the bulk crystalline thermoelectric material matrix. The nanoparticles may be metal particles or ceramic particles. The term “embedding” indicates that the nanoparticles are not solidified in crystalline form in the thermoelectric material matrix, but are buried in the thermoelectric material matrix, except for a structure in which the nanoparticles substitute metal atoms in the crystalline matrix and form chemical bonds. The embedded structure may be a structure in which the nanoparticles are independently introduced into a crystalline interface or inside the crystals of the thermoelectric material matrix.

The thermal conductivity of the thermoelectric material may be decreased since free migration of phonons is inhibited by embedding nanoparticles having a particular size in the thermoelectric material matrix. Thus, a bulk thermoelectric device having a volume of about several cubic millimeters (mm³) to about several cubic centimeters (cm³) may have a phonon blocking-electron transmitting structure. Thus, the figure of merit ZT may be significantly increased by decreasing thermal conductivity while maintaining electrical conductivity and the Seebeck coefficient, i.e., power factor. Due to the bulk structure of the thermoelectric material, the manufacture of the thermoelectric material may be easily performed in a cost-effective manner with high efficiency. Furthermore, the thermoelectric material may be readily applied to a large area, and the size of the crystals may be easily controlled.

As described above, the nanoparticles may be introduced into a crystalline interface or inside the crystals of the thermoelectric material matrix. In one embodiment, the nanoparticles may be introduced into the crystalline interface since the migration of phonons is largely influenced by the crystalline interface.

In addition, since the conductive material is coated on the surface of the nanoparticles to a thickness of several nanometers (nm), an interface having a thickness of several nm in which phonons may be scattered is formed. Thus, the thermal conductivity may be further reduced by the scattering of phonons by the nanoparticles and by the scattering of phonons in the interface formed by the conductive material coated on the nanoparticles.

In addition, carriers may be easily transmitted in the thermoelectric material due to the coated conductive material. For example, the carriers may be continuously transmitted in the conductive material, and thus reduction of the electrical conductivity caused by the scattering due to the nanoparticles may be efficiently controlled.

The conductive material may be chemically combined with the surface of the nanoparticles or physically attached to the surface of the nanoparticles. In addition, the conductive material may be coated on a portion of or on the entire surface of the nanoparticles. About 30 to about 100% of the surface of the nanoparticles may be coated with the conductive material. If the coated area with the conductive material is too small, the reduction of electrical conductivity may not be sufficiently inhibited. On the other hand, if the coated area with the conductive material is too large, for example, if the entire surface of the metal or ceramic particles is coated with the conductive material to form a core/shell structure, agglomeration of the nanoparticles may be inhibited.

The conductive material may be coated on the surface of the metal or ceramic particles to a thickness that is sufficient to form a path for the carriers. The thickness of the conductive material may be from about to 1 to about 10 nm, particularly from about 1 to about 5 nm, in order to induce phonon scattering in the interface formed by the coating.

Any material that has electrical conductivity and can withstand high temperatures during a sintering process for forming the thermoelectric material may be used as the conductive material without limitation. In one embodiment the conductive material coating layer is formed by coating the nanoparticles using a conductive carbon raw material such as an organic polymer (e.g., polymethyl methacrylate), an organic surfactant optionally containing a charged group such as a phosphate, a silicon-containing group, or a nitrogen-containing group such as an imidazole, or a combination thereof, and then heat treating the coated raw materials to produce a conductive material coating layer. Thus, the conductive material coating layer mainly includes conductive carbon, but may also include residues from the phosphate, silicon groups, nitrogen-containing groups, or the like.

As stated above, the nanoparticles on which the conductive material is coated may be metal particles or ceramic particles. The ceramic particles may include at least one selected from the group consisting of an oxide, a nitride, a carbide, any mixture thereof, and any complexes thereof. For example, the ceramic particles may be SiO₂, Al₂O₃, TiO₂, MgO, ZnO, ZrO₂, Ta₂O₅, BaTiO₃, SiC, TiC, WC, ZrC, AIN, TiN, Si₃N₄, any mixture thereof, or any complexes thereof.

The metal particles may include at least one selected from the group consisting of aluminum (Al), titanium (Ti), lead (Pb), barium (Ba), silicon (Si), tin (Sn), magnesium (Mg), niobium (Nb), zirconium (Zr), iron (Fe), tungsten (W), vanadium (V), manganese (Mn), cobalt (Co), nickel (Ni), zinc (Zn), and rare-earth metal elements.

In addition, a binding force between the nanoparticles, e.g., metal or ceramic particles, and the conductive material is greater than that between the atoms in the crystalline structure of the thermoelectric material matrix. In this regard, since the metal or the ceramic particles constituting the nanoparticles are not easily separated from the conductive material, the nanoparticles may not be inserted into the crystalline structure of the matrix. Instead, they are applied during the process of preparing the thermoelectric material by alloying the nanoparticles and the thermoelectric material matrix. As a result, the introduction of heterogeneous atoms does not induce reduction in the concentration of carriers, but instead maximizes the phonon scattering effect.

Each of the mean diameter of the nanoparticles and the thickness of the conductive material may be similar to the size of a mean free path of the phonons. For example, the difference between the diameter of the nanoparticles and the mean free path of the phonons and between the thickness of the conductive material and the mean free path of the phonons may respectively be from 0 to about 7 nm, specifically from 0 to about 5 nm. In this regard, the “mean free path” is a mean distance in which particles, such as molecules, may freely migrate without colliding with each other. The mean free path of the phonons is considered in a thermoelectric material matrix that does not include nanoparticles. The size of the mean free path of the phonons may vary according to the type and crystalline shape of the thermoelectric material matrix, and may be several to several tens of nanometers.

In addition, the diameter of the nanoparticles may be in a range that does not interfere with the migration of carriers. For example, if the diameter of the nanoparticles is too large, the phonon scattering effect may not be sufficient when the same volume is used. Thus, the mean diameter of the nanoparticles may be in a range that does not interfere with the migration of carriers, for example, from about 1 nm to about 50 nm, or about 1 to about 15 nm. In addition, the thickness of the coated conductive material may be from about 1 to about 10 nm, for example, about 1 to about 5 nm.

According to an embodiment, the nanoparticles, which are referred to herein as primary particles, may form secondary particles in the thermoelectric material matrix. For example, the nanoparticles (primary particles) may be agglomerated to form the secondary particles. Since the surface of the nanoparticles is coated with the conductive material, the secondary particles may not interfere with the migration of the carriers. If the nanoparticles (primary particles) form the secondary particles, a mean diameter D50 of the nanoparticles (primary particles) may be from about 1 to about 10 nm, and a mean diameter D50 of the secondary particles may be from about 10 to 100 nm.

In addition, the shapes of the nanoparticles may vary. The nanoparticles may have a spherical shape in consideration of manufacturing convenience and the degree of scattering, but the shape is not limited thereto. If desired, the nanoparticles may be surface treated, for example, surface treated for inhibiting agglomeration.

Further according to one embodiment, the bulk thermoelectric material matrix has crystallinity, and may include at least two elements selected from the group consisting of bismuth (Bi), antimony (Sb), tellurium (Te), and selenium (Se).

For example, the thermoelectric material matrix may have a structure represented by the formula [A]₂[B]₃, wherein A is at least one of Bi and Sb, and B is at least one of Te and Se. A thermoelectric material matrix formed using a Bi—Te-based compound may have excellent thermoelectric properties at a temperature around room temperature, and thus can be used to dissipate heat of a highly integrated device and various sensors.

In the thermoelectric material, if the nanoparticles are introduced into the crystalline interfaces of the thermoelectric material matrix, the nanoparticles are more uniformly distributed and the effects of phonon scattering may be increased as the size of the crystals of the thermoelectric material matrix is decreased. In one embodiment, the crystalline thermoelectric material matrix may have a nanostructure. In this regard, the “nanostructure” is a structure in which the thermoelectric material matrix has nano-sized crystalline particles, wherein “nano” refers to a size in the range of about several to about several hundreds of nanometers.

Although the amount of the nanoparticles is not specifically limited, if the amount of the nanoparticles is too large, the nanoparticles become over-agglomerated, thereby inhibiting the migration of carriers. If the amount of the nanoparticles is too small, phonon scattering may not be obtained. In one embodiment the volume of the nanoparticles may be from about 0.5 to about 15%, and preferably about 1 to about 5%, of the total volume of the thermoelectric material.

According to an embodiment, the thermoelectric material may be prepared using a method including: coating a conductive material on the surface of nanoparticles such as metal or ceramic particles; preparing a thermoelectric material powder that forms a thermoelectric material matrix during a sintering process; mixing the nanoparticles with the thermoelectric material powder using a dry method; and sintering the mixture.

The coating of the conductive material on the surface of the nanoparticles such as the metal or ceramic particles may be performed using any known method. For example, metal or ceramic particles and a raw material of the conductive material (as further described below) can be added to an organic solvent and stirred to coat the raw material onto the surface of the metal or ceramic particles, and the organic solvent can be then volatilized by heat treating the resultant slurry.

Any material that is retained on the surface of the metal or ceramic particles during a heat-treatment process may be used as the raw material for the conductive material, for example an organic polymer such as a polymethyl methacrylate. An organic surfactant may also be used (alone or in conjunction with another raw material) as the raw material for the conductive material in order to uniformly coat the conductive material on the surface of the metal or ceramic particles. For example, the raw material for the conductive material may include at least one selected from the group consisting of a phosphate surfactant, a silicon surfactant, and an imidazole surfactant. For example, the raw material may be polymethyl methacrylate having a molecular weight of about 200 to about 30,000, polyvinyl alcohol having a molecular weight of about 200 to about 30,000, nonionic surfactants such as those available under the trade names Triton®-X and Tergitol®, phosphoric acid ethoxylated nonylphenyl ether, or the like, or a combination thereof. In this regard, a conductive material including carbon may be uniformly coated on the surface of the nanoparticles, for example, metal particles or ceramic particles.

The organic solvent may be ethyl acetate, ethyl alcohol, or the like, but is not limited thereto.

The thermoelectric material powder may be prepared using a mechanical alloying method in consideration of manufacturing convenience and the nanocrystalline structure, but is not limited thereto if a precursor capable of forming the thermoelectric material matrix is formed in a sintering process that will be described later.

The mechanical alloying method may be performed by adding raw material powder and steel balls to a cemented carbide jar and stirring the mixture so that the steel balls mechanically impact the raw material powder. In particular, the mechanical alloying method may be performed using a vibratory ball mill, a rotary ball mill, a planetary ball mill, or an attrition mill, but is not limited thereto. Further, the mechanical alloying method may be a bulk mechanical alloying method.

In addition, the nanoparticles and the thermoelectric material powder may be mixed using a dry method, for example, using one of a ball mill, a planetary ball mill, an attrition mill, a SPEX mill (SPEX industries, Edison, N.J.), or a jet mill.

In addition, the sintering process may be performed using a known method. According to an embodiment, the previously prepared mixture is added to a mold and a spark plasma sintering process is performed. Since the sintering is quickly performed by using the spark plasma sintering process, crystallographic orientation may be increased. In addition, a thermoelectric material having high mechanical strength may be prepared by increasing the density of and controlling the structure of the thermoelectric material. In particular, if the spark plasma sintering process is used, the thermoelectric material having an initial nanostructure or nano-sized shape may be prepared in bulk form by using nanostructure thermoelectric material powder or nanoparticles.

The spark plasma sintering process may be performed, for example, by introducing a pulverized raw material powder into a mold, establishing a vacuum in a chamber containing the mold using a vacuum pump, introducing gas into the chamber to apply pressure to the mold, and treating the powder with plasma in a plasma zone formed in the central portion of the mold.

The gas may be Ar, H₂, O₂, or the like, but is not limited thereto.

If the pressure in the chamber is too high or too low during the plasma process, it is difficult to generate plasma or perform a plasma treatment. Thus, the pressure may be from about 50 to about 100 megapascals (MPa). In addition, if the plasma treatment time is too short or the heating rate is too low, it is difficult to sufficiently perform the plasma treatment. Thus, the plasma treatment may be performed at a temperature of about 200 to about 600 degrees Celsius (° C.), and at a heating rate of about 50 degrees Celsius per minute (° C./min) for about 1 to about 10 minutes.

According to an embodiment, there is provided a thermoelectric device manufactured by molding the thermoelectric material using a process such as cutting-off.

The thermoelectric device may be a p-type thermoelectric device or an n-type thermoelectric device. The thermoelectric device includes thermoelectric materials arranged in a particular shape, for example, in a rectangular shape.

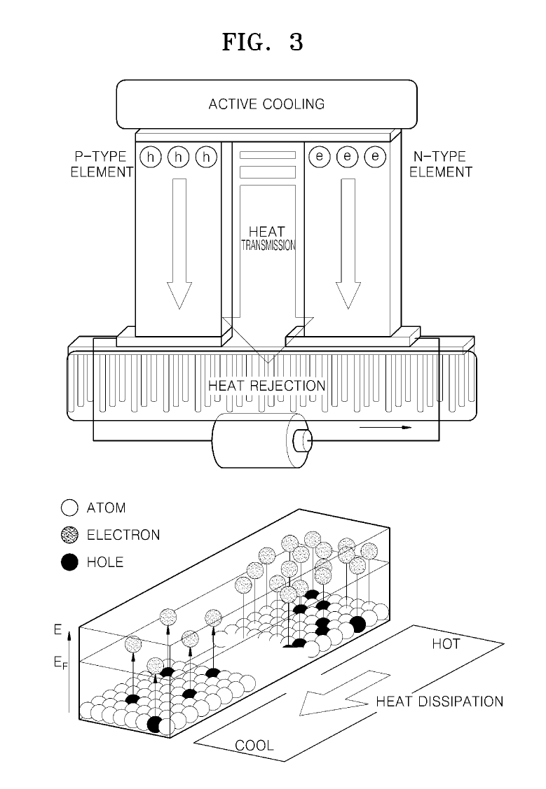

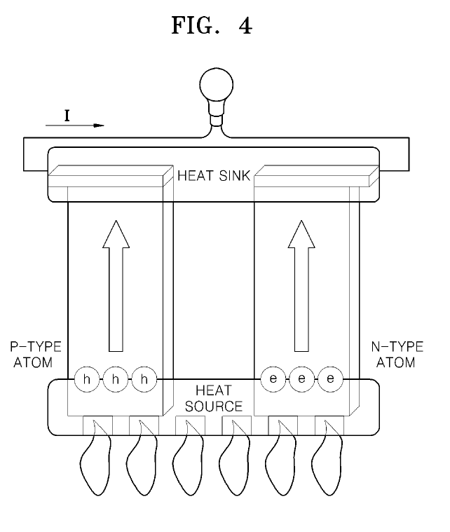

The thermoelectric device is combined with an electrode, and thus may be a device having cooling effects due to current supply as illustrated in FIG. 3, or a device having power-generating effects due to a temperature difference, as illustrated in FIG. 4.

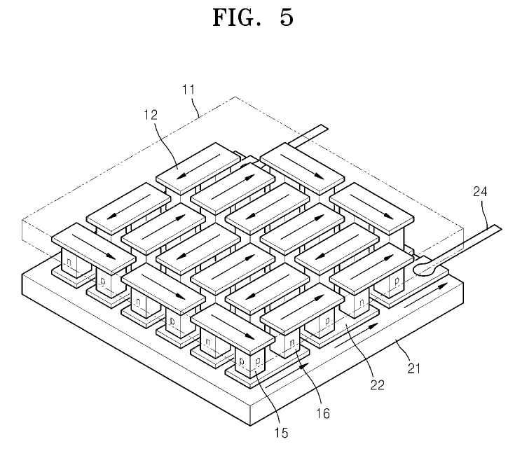

FIG. 5 schematically illustrates an exemplary thermoelectric module employing the thermoelectric device described above, according to an embodiment. Referring to FIG. 5, the thermoelectric module includes upper electrodes 12 patterned in an upper insulating substrate 11, and lower electrodes 22 patterned in a lower insulating substrate 21. A p-type thermoelectric device 15 and an n-type thermoelectric device 16 contact both of the upper electrodes 12 and the lower electrodes 22. The upper electrodes 12 and the lower electrodes 22 are connected to an external device via a lead electrode 24.

The upper insulating substrate 11 and the lower insulating substrate 21 may be formed of alumina (Al₂O₃), zirconia (ZrO₂), beryllia (BeO), or ceramic-coated metal substrate. The upper electrodes 12 and the lower electrodes 22 may be formed of copper, gold, silver, platinum, aluminum, nickel, titanium, Cu—Mo, or the like, and in various sizes. The upper electrodes 12 and the lower electrodes 22 may be patterned using a known method without limitation, for example, a lift-off semiconductor process, deposition, or photolithographic process.

The thermoelectric module may be a thermoelectric cooling system or a thermoelectric power generating system. The thermoelectric cooling system may be a micro-cooling system, a universal cooling device, an air handling unit, a waste heat recovery system, or the like, but is not limited thereto. The configuration of and method of manufacturing the thermoelectric cooling system are known in the art, and will not be described herein.

The present invention will now be described in greater detail with reference to the following examples. The following examples are for illustrative purposes only and are not intended to limit the scope of the invention.

### Example 1

1-1: Preparation of C-Coated TiO₂ nanoparticles

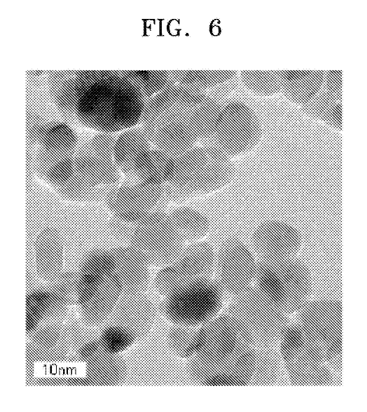

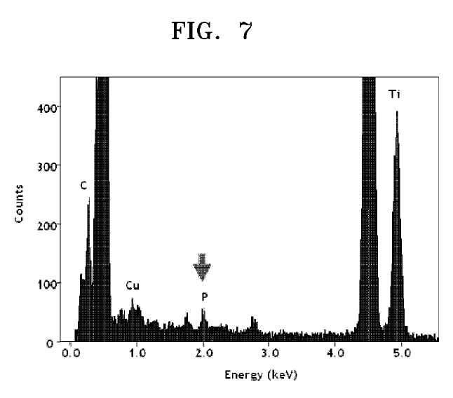

Powder of TiO₂ nanoparticles having a mean diameter of about 7 nm and phosphoric acid ethoxylated nonylphenyl ether, represented by Formula 1 below, as a phosphate surfactant were added to ethyl acetate solvent, and the solution was ultrasonically stirred for 30 minutes. The solvent was completely volatilized using a rotary vacuum evaporator in a constant-temperature bath at 60° C. to obtain dried powder. Then, the resultant was heat-treated at 350° C. for 1 hour and pulverized to prepare a powder of titanium oxide (C-coated TiO₂) nanoparticles, on which a layer of conductive material including carbon and a small amount of phosphate and having a thickness of 3 nm or less was formed, having a mean diameter D50 of about 7 to about 10 nm. FIG. 6 is a transmission electron microscope (“TEM”) image of the prepared nanoparticles coated with the conductive material. FIG. 7 is a graph illustrating the results of the energy dispersive spectrometer (“EDS”) element analysis of the nanoparticles coated with the conductive material. According to FIG. 7, Ti, O and C were detected as main elements, and a small amount of P was detected. According to the TEM image of FIG. 6, the surface of the nanoparticles including carbon is uniformly formed. Thus, it was identified that the carbon coating layer is uniformly formed on the surface of the powder of the nanoparticles.

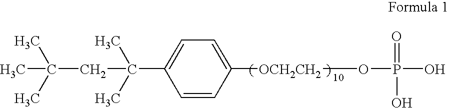

### 1-2: Preparation of Powder of Bi_{0.5}Sb_{1.5}Te₃

P-type Bi_{0.5}Sb_{1.5}Te₃ powder as a material for a matrix was prepared using an attrition mill. Raw materials including Bi, Sb, and Te were combined with steel balls having a diameter of 5 millimeters (mm), in which a weight ratio of the raw materials to the steel balls is 1:20. The raw materials and steel balls were added to a jar formed of cemented carbide, and Ar gas was flowed therein in order to inhibit oxidation of the raw materials. An impeller formed of cemented carbide was rotated in the jar at 500 rpm, and cooling water was flowed outside of the jar in order to inhibit oxidation of the raw materials caused by heat generated by the rotation.

### 1-3: Preparation of Mixture

The powder of the nanoparticles prepared according to operation 1-1 above was mixed with the powder of Bi_{0.5}Sb_{1.5}Te₃, which was prepared according to operation 1-2 above using a dry-type ball mill, such that the volume of the powder of the nanoparticles was 3% of the combined volume of the two powders used to prepare the mixture powder.

### 1-4: Preparation of Thermoelectric Material

The mixture powder prepared according to operation 1-3 above was added to a cemented carbide mold, and then plasma-sintered in a vacuum (10⁻³ torr or less) at 70 MPa at 400° C. The resultant was hot pressed to prepare a thermoelectric material.

### Example 2

Thermoelectric materials were prepared in the same manner as in Example 1, except that 1% by volume and 5% by volume of the powder of nanoparticles were respectively used instead of 3% by volume of the powder of nanoparticles used in operation 1-1 of Example 1.

### Example 3

A thermoelectric material was prepared in the same manner as in Example 1, except that a mixture including TiO₂, SiO₂, Al₂O₃, and ZrO₂ was used instead of the TiO₂ nanoparticles used to prepare the nanoparticles in operation 1-1 of Example 1.

### Example 4

A thermoelectric material ingot including Co and Sb was prepared using a melting method, and a thermoelectric material powder was prepared by mechanical pulverization using an attrition mill.

A thermoelectric material was prepared in the same manner as in operation 1-4 of Example 1, except that SiO₂, Al₂O₃, or ZrO₂ nanoparticles were respectively used instead of the TiO₂ nanoparticles in operation 1-1 of Example 1, and 1%, 3%, 5%, 7%, 10%, and 15% by volume of the nanoparticles were respectively used in operation 1-3 of Example 1.

### Example 5

A thermoelectric material was prepared in the same manner as in Example 4, except that Pb and Te were used instead of Co and Sb.

### Example 6

A thermoelectric material was prepared in the same manner as in Example 4, except that Zn and Sb were used instead of Co and Sb.

### Example 7

A thermoelectric material was prepared in the same manner as in Example 4, except that Si and Ge were used instead of Co and Sb.

### Comparative Example 1

A thermoelectric material was prepared in the same manner as in operation 1-4 of Example 1 by preparing the powder of p-type Bi_{0.5}Sb_{1.5}Te₃ in the same manner as in operation 1-2 of Example 1, except that the powder of the nanoparticles was not used.

### Experimental Example

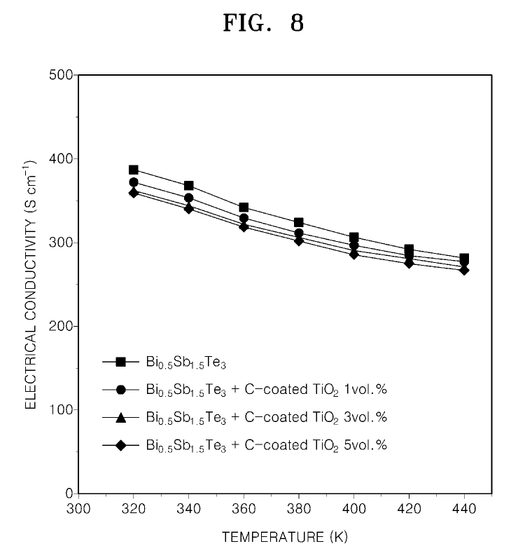

Electrical conductivity (S cm⁻¹), Seebeck coefficient (mW K⁻¹), thermal conductivity (W m⁻¹K⁻¹), and figure of merit ZT, according to temperature (K), of the thermoelectric materials prepared according to Examples 1 and 2 and Comparative Example 1 were measured, and the results are shown in the graphs of FIGS. 8 to 11. The electrical conductivity, Seebeck coefficient, and figure of merit ZT were measured for thermoelectric devices manufactured using the thermoelectric materials prepared according to Examples 1 and 2 and Comparative Example 1. In this regard, the thermoelectric materials prepared according to Examples 1 and 2 and Comparative Example 1 were cut into a size of 3 mm×3 mm×8 mm and processed, in order to form the thermoelectric devices. The thermal conductivity was measured using thermoelectric devices manufactured using the thermoelectric materials prepared according to Examples 1 and 2 and Comparative Example 1. In this regard, the thermoelectric materials prepared according to Examples 1 and 2 and Comparative Example 1 were cut into disks having a thickness of 1 mm and a diameter of 1 cm and processed, in order to form the thermoelectric devices.

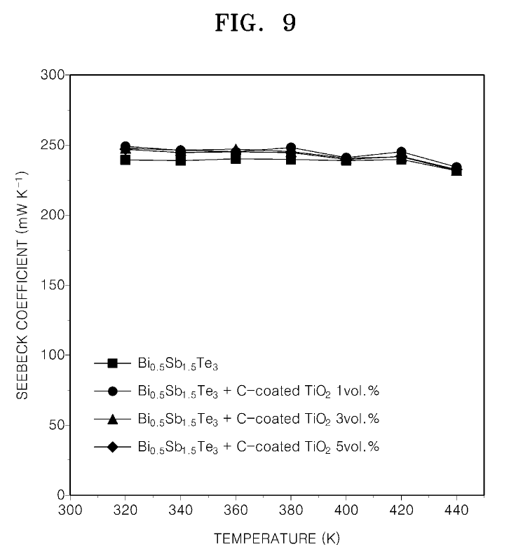

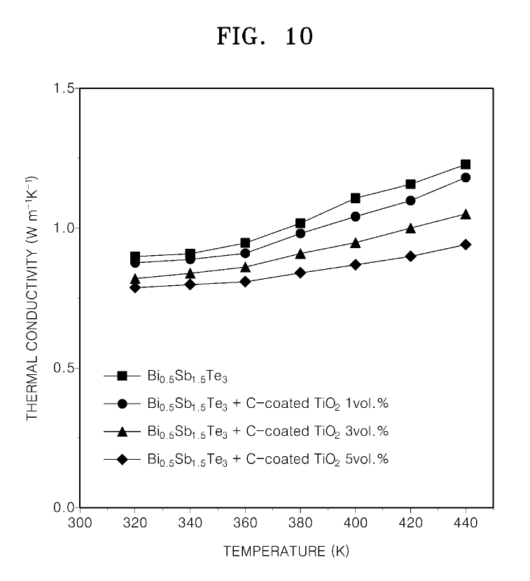

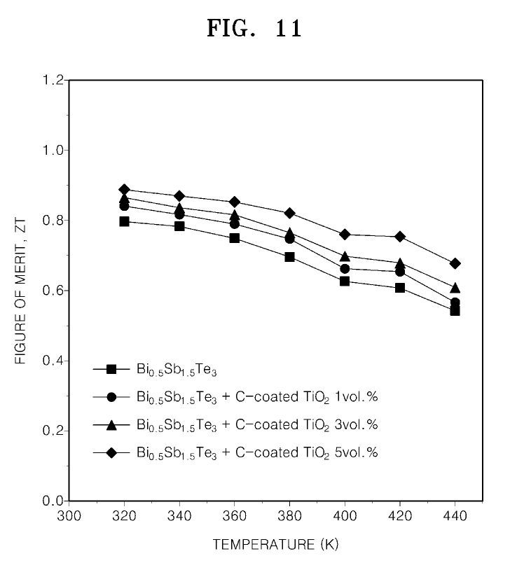

Referring to FIG. 8, the electrical conductivity of the thermoelectric materials, including TiO₂ nanoparticles coated with carbon, prepared according to Examples 1 and 2 was less than that of the thermoelectric material prepared according to Comparative Example 1. Referring to FIG. 9, the Seebeck coefficient of the thermoelectric materials prepared according to Examples 1 and 2 was greater than that of the thermoelectric material prepared according to Comparative Example 1. In addition, referring to FIG. 10, the thermal conductivity of the thermoelectric materials prepared according to Examples 1 and 2 was less than that of the thermoelectric material prepared according to Comparative Example 1 for the entire temperature range (320-440K), and the difference increased as the temperature was increased. Furthermore, referring to FIG. 11, the ZT value of the thermoelectric materials prepared according to Examples 1 and 2 was greater than that of the thermoelectric material prepared according to Comparative Example 1 in all temperature ranges. In particular, the figure of merit ZT value of the thermoelectric materials of Examples 1 and 2 is more than 30% greater than that of the thermoelectric material of Comparative Example 1 at a temperature of 400K. Thus, it was identified that the thermoelectric effect was increased in a high temperature range by introducing metal or ceramic nanoparticles coated with the conductive material into the thermoelectric material matrix.

According to an embodiment, the figure of merit ZT of the thermoelectric material may be increased by introducing nanoparticles coated with a conductive material into a bulk crystalline thermoelectric material matrix.

It should be understood that the exemplary embodiments described herein should be considered in a descriptive sense only and not for purposes of limitation. Descriptions of features or aspects within each embodiment should typically be considered as available for other similar features or aspects in other embodiments.

What is claimed is:

1. A thermoelectric material comprising: a bulk crystalline thermoelectric material matrix; and nanoparticles coated with a conductive material within the thermoelectric material matrix.

2. The thermoelectric material of claim 1, wherein the nanoparticles coated with the conductive material are embedded in the bulk crystalline thermoelectric material matrix.

3. The thermoelectric material of claim 1, wherein the nanoparticles coated with the conductive material are introduced into a crystalline interface or inside a crystal of the thermoelectric material matrix.

4. The thermoelectric material of claim 1, wherein the nanoparticles are metal particles or ceramic particles.

5. The thermoelectric material of claim 4, wherein the ceramic particles comprise at least one selected from the group consisting of a metal oxide, a metal nitride, a metal carbide, a ceramic oxide, a ceramic nitride, a ceramic carbide, any mixtures thereof, and any complexes thereof.

6. The thermoelectric material of claim 4, wherein the metal particles comprise at least one selected from the group consisting of aluminum, titanium, lead, barium, silicon, tin, magnesium, niobium, zirconium, iron, tungsten, vanadium, manganese, cobalt, nickel, zinc, a rare-earth metal element, and a mixture thereof.

7. The thermoelectric material of claim 1, wherein the conductive material comprises carbon.

8. The thermoelectric material of claim 1, wherein about 30 to about 100% of the surface of the nanoparticles is coated with the conductive material.

9. The thermoelectric material of claim 1, wherein a thickness of the conductive material is about 1 to about 10 nm.

10. The thermoelectric material of claim 1, wherein a binding force between the nanoparticles and the conductive material is greater than that between atoms in the crystalline structure of the thermoelectric material matrix.

11. The thermoelectric material of claim 1, wherein the difference between a diameter of the nanoparticles and a mean free path of phonons is from 0 to about 7 nm.

12. The thermoelectric material of claim 1, wherein the difference between a thickness of the conductive material coated on the nanoparticles and a mean free path of the phonons is from 0 to about 5 nm.

13. The thermoelectric material of claim 1, wherein a diameter of the nanoparticles is about 1 to about 50 nm.

14. The thermoelectric material of claim 1, wherein the nanoparticles have a spherical shape.

15. The thermoelectric material of claim 1, wherein the crystalline thermoelectric material matrix comprises at least one selected from the group consisting of bismuth, antimony, tellurium, and selenium.

16. The thermoelectric material of claim 15, wherein the crystalline thermoelectric material matrix has a structure represented by the formula [A]₂[B]₃, wherein A is at least one of Bi and Sb, and B is at least one of Te and Se.

17. The thermoelectric material of claim 1, wherein the crystalline thermoelectric material matrix has a nanostructure.

18. The thermoelectric material of claim 1, wherein a volume of the nanoparticles is about 0.5 to about 15% of the total volume of the thermoelectric material.

19. A thermoelectric device comprising a thermoelectric material, which comprises a bulk crystalline thermoelectric material matrix; and nanoparticles coated with a conductive material within the thermoelectric material matrix;
wherein the thermoelectric device is a p-type thermoelectric device or an n-type thermoelectric device.

20. A thermoelectric module comprising a thermoelectric device comprising a thermoelectric material, which comprises a bulk crystalline thermoelectric material matrix; and nanoparticles coated with a conductive material within the thermoelectric material matrix;
wherein the thermoelectric module is a thermoelectric cooling system or a thermoelectric power generating system.
